(19) United States
(12) Patent Application Publication
(10) Pub. No.: US 2024/0387241 A1
(43) Pub. Date: Nov. 21, 2024

(54) STRUCTURE OF HIGH-RESISTIVITY SILICON-ON-INSULATOR EMBEDDED WITH CHARGE CAPTURE LAYER AND MANUFACTURE THEREOF

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Hongtao XU, Shanghai (CN); Meng CHEN, Shanghai (CN); Ziwen WANG, Shanghai (CN); Minghao LI, Shanghai (CN); Wei LI, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 18/660,384

(22) Filed: May 10, 2024

(30) Foreign Application Priority Data
May 19, 2023 (CN) 202310572297.8

(51) Int. Cl. H01L 21/762; H01L 21/3065; H01L 21/324; H01L 27/12

(52) U.S. Cl. CPC H01L 21/7624; H01L 21/3065; H01L 21/324; H01L 27/1203

(57) ABSTRACT

The present application provides a structure of HR-SOI embedded with a charge capture layer and manufacture thereof. The process for manufacturing a structure of HR-SOI embedded with a charge capture layer comprises: providing a first substrate, wherein the first substrate has a first surface, and a pinning layer is formed on the first surface by a deposition process, and homogenizing the pinning layer surface by dry etching to adjust a thickness uniformity of the pinning layer. Accordingly, the thickness uniformity of the obtained polysilicon film is able to reach a good state.

### BACKGROUND OF THE INVENTION

### 1. Field of the Invention

The present application relates to a technical field of semiconductor manufacture, and more particularly to a structure and a manufacturing process of silicon-on-insulator.

### 2. Description of the Related Art

Currently, silicon-on-insulator (SOI) has been broadly applied in the fields of microelectronics, optics, and optoelectronics, and there are correspondently more challenges for materials. Because of the increasingly strict requirements for radio frequency front-end of smart devices in 5G, radio frequency SOI (RF-SOI) can be widely applied.

RF-SOI includes high-resistivity silicon-on-insulator (HR-SOI) and trap-rich high-resistivity silicon-on-insulator (TR-SOI). In HR-SOI, a high-resistance silicon substrate is used to prepare the SOI structure to maintain certain linearity and lower RF loss at high frequencies. As an extension product of HR-SOI, TR-SOI has a pinning layer embedded between an insulating buried oxide layer (BOX) and the high-resistance silicon substrate, which can effectively pin free carriers at high frequencies. Thereby the radio frequency performance of the high-resistance silicon substrate can be enhanced. Polysilicon film is usually selected to be the pinning layer, such that the preparation process of the polysilicon film is crucial.

The thickness uniformity of the polysilicon film is one of the key parameters of TR-SOI, which is able to directly decide the uniformity of the overall SOI structure and the yield of subsequent processes. Due to the limited temperature uniformity of the deposition equipment for the formation of polysilicon film, the thickness uniformity of the obtained polysilicon film cannot reach a good state. However, under the current circumstances, the thickness uniformity of the polysilicon film has not been seriously considered in manufacture of TR-SOI.

### SUMMARY

The purpose of the present application is to provide a structure of HR-SOI embedded with a charge capture layer and manufacture thereof, which can improve a thickness uniformity of a polysilicon film.

To solve the above mentioned problems, the present application provides a process for manufacturing a structure of HR-SOI embedded with a charge capture layer comprising: providing a first substrate having a first surface, forming a pinning layer on the first surface by deposition, and homogenizing the pinning layer surface by dry etching.

### BRIEF DESCRIPTION OF THE DRAWINGS

FIG. 1 shows, in accordance with one embodiment of the present application, a process for manufacturing a structure of HR-SOI embedded with a charge capture layer.

FIG. 2 to FIG. 4 show, in accordance with one embodiment of the present application, the structural of each step in the process for manufacturing a structure of HR-SOI embedded with a charge capture layer.

### DETAILED DESCRIPTION OF THE EMBODIMENTS

The present application provides a process for manufacturing a structure of HR-SOI embedded with a charge capture layer comprising: providing a first substrate having a first surface, forming a pinning layer on the first surface by deposition, and homogenizing the pinning layer surface by dry etching.

In one embodiment, the step of homogenizing the pinning layer surface comprising: in a chemical vapor deposition reactor, treating a surface of the pinning layer by hydrogen chloride (HCl) in situ etching to adjust a thickness uniformity of the pinning layer.

Further, the etching of the pinning layer surface is conducted under an atmosphere of a gaseous mixture of HCl and hydrogen (H₂). In the gaseous mixture, a ratio of HCl to H₂ is 1:100-1:5. The etching temperature is more than 1000° C.

In one embodiment, after the homogenizing step, an annealing step is conducted.

In one embodiment, after the formation of pinning layer and before the homogenizing step, an annealing step is conducted.

In one embodiment, the process further comprises: prior to the formation of pinning layer, forming a surface treatment layer on the first surface of the first substrate, wherein the surface treatment layer is an oxide layer, a nitride layer or an oxynitride layer.

Further, in one embodiment, while the surface treatment layer is an oxide layer, the first surface is cleaned and washed to form the oxide layer. In other embodiment, while the surface treatment layer is a nitride layer or an oxynitride layer, the first surface is cleaned and washed to form an oxide layer, and the oxide layer is nitrided to form the nitride layer or the oxynitride layer.

Further, the formation of pinning layer comprises: in a chemical vapor deposition reactor, forming a pinning layer on the first surface by chemical vapor deposition, wherein the pinning layer is a polysilicon film layer.

In another aspect, the present application provides a HR-SOI embedded with a charge capture layer characterized by, manufactured by the above mentioned process, and having a structure comprising a first substrate, a surface treatment layer and a pinning layer stacked in sequence, wherein the first substrate has a first surface, and the surface treatment layer and the pinning layer are formed on the side of the first surface, and the pinning layer is subjected to homogenizing treatment by dry etching.

In one embodiment, the structure further comprises an insulating buried oxide layer and a second substrate stacked in sequence on the pinning layer.

Comparing with conventional techniques, the present application has the following advantages.

The present application provides a structure of HR-SOI embedded with a charge capture layer and manufacture thereof. The process for manufacturing a structure of HR-SOI embedded with a charge capture layer comprises: providing a first substrate, wherein the first substrate has a first surface, and a pinning layer is formed on the first surface by a deposition process, and homogenizing the pinning layer surface by dry etching to adjust a thickness uniformity of the pinning layer. Accordingly, the thickness uniformity of the obtained polysilicon film is able to reach a good state.

### EXAMPLES

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Example embodiments will now be described more fully with reference to the accompanying drawings. Noted that accompanying drawing is simplified and applies non-accurately ratio for the purpose of clear and convenient illustration of the example of the present invention.

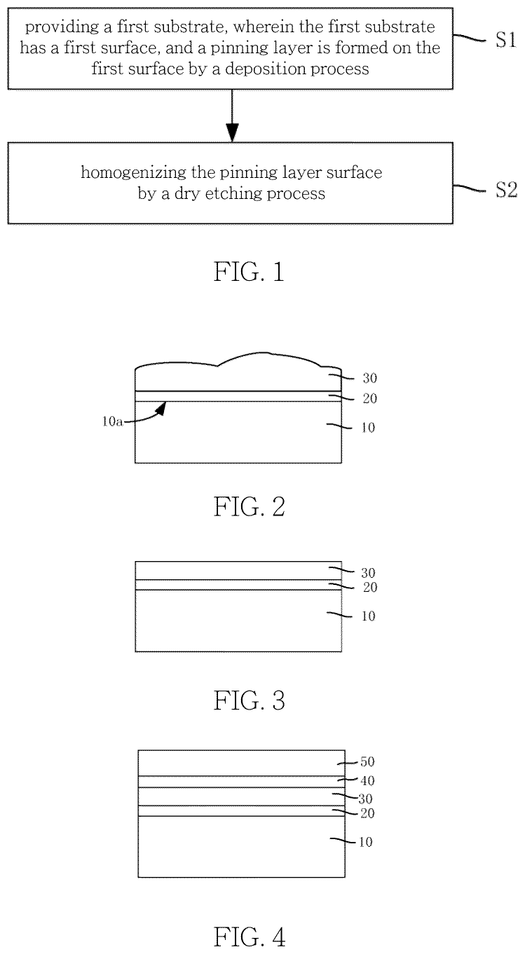

FIG. 1 shows, in accordance with one embodiment of the present application, a process for manufacturing a structure of HR-SOI embedded with a charge capture layer. As shown in FIG. 1, the process comprises the following steps.

Step S1: providing a first substrate, wherein the first substrate has a first surface, and a pinning layer is formed on the first surface by a deposition process; and
Step S2: homogenizing the pinning layer surface by dry etching.

With reference to FIGS. 2-4, the process of the present application will be described in detail.

As shown in FIG. 2 and FIG. 3, the Step S1 is firstly conducted. A first substrate 10 is provided. The first substrate 10 has a first surface 10a, and a pinning layer 30 is formed on the first surface 10a by a deposition process.

In this step, as shown in FIG. 2, the first substrate 10 can be a monocrystalline silicon semiconductor wafer with high resistivity. In one embodiment, the resistivity of the first substrate 10 can be 1 kΩ-10 kΩ. The first substrate 10 has a front surface 10a and a back surface opposite to the first surface 10a.

Step S12: forming a surface treatment layer 20 on the first surface 10a, is conducted.

The surface treatment layer 20 can be an oxide layer, a nitride layer or an oxynitride layer.

When the surface treatment layer 20 is the oxide layer, this step includes: cleaning the first surface 10a to form an oxide layer. In one embodiment, the oxide layer has a thickness of about 1.5 nm. In one embodiment, the cleaning solution can be SC1 mixed acids. The cleaning solution can have an ozone (O3) concentration of 10 ppm-50 ppm. The washing temperature is 35° C.-70° C.

When the surface treatment layer 20 is the nitride layer or the oxynitride layer, this step includes the following.

Firstly, the first surface 10a is cleaned to form an oxide layer. In one embodiment, the oxide layer has a thickness of about 1.5 nm. In one embodiment, the cleaning solution can be SC1 mixed acids. The cleaning solution can have an ozone (O3) concentration of 10 ppm-50 ppm. The washing temperature is 35° C.-70° C.

Subsequently, nitriding of the oxide layer is conducted to form the nitride layer or the oxynitride layer. In one embodiment, the first substrate 10 is loaded into a CVD reactor. The loading temperature can be 500° C.-800° C., preferably 650° C. The atmosphere is hydrogen. Then, the loading temperature is increased to a first temperature to initiate the nitriding step to the oxide layer. At the nitriding step, the atmosphere is transferred to nitrogen atmosphere, the gas flow rate of nitrogen can be 40 slm-80 slm. The first temperature can be 850° C.-1000° C., preferably 900° C.-950° C. The reaction time can be 10 s-120 s, preferably 30 s-60 s.

As shown in FIG. 3, Step S13: forming a pinning layer 30 on the surface treatment layer 20 via chemical vapor deposition, is conducted. In one embodiment, after the completion of the nitriding treatment, the temperature of the CVD reactor is adjusted to a second temperature to conduct atmospheric pressure chemical vapor deposition (APCVD) to the first substrate 10. The atmosphere is transferred to a gaseous mixture of hydrogen and trichlorosilane (TCS). The gas flow rate of TCS can be 10 slm-20 slm, preferably 12 slm-16 slm. The gas flow rate of hydrogen can be 40 slm-80 slm, preferably 60 slm. The second temperature can be 850° C.-1000° C., preferably 900° C.-950° C. The reaction time of APCVD can be adjusted depending on the thickness requirement for the pinning layer 30. In this example, the pinning layer 30 is a polysilicon film layer. At this stage, the pinning layer 30 formed by APCVD process has a poor thickness uniformity.

Subsequently, the Step S2 is conducted to homogenize the surface of the pinning layer 30 by dry etching.

In this step, the surface of the pinning layer 30 is treated by HCl in situ etching to adjust a thickness uniformity of the pinning layer 30.

After the completion of APCVD, the temperature is increased to a third temperature to initiate to vapor etch the pinning layer 30. The atmosphere is transferred to a gaseous mixture of hydrogen and HCl. In the gaseous mixture, the ratio of HCl: H₂ can be 1:100-1:5, preferably 1:20-1:10. The third temperature can be more than 1000° C., preferably 1100° C.-1150. The heating rate can be 0.5° C./min-20° C./min.

Then, the atmosphere is transferred to hydrogen. The temperature is cooled down to 500° C.-800° C., preferably 650° C. The cooling rate is 1° C./min-10° C./min, preferably 3° C./min-5° C./min.

In one embodiment, an annealing step is conducted to eliminate the stress in the polysilicon film layer and remove the hydrogen within the polysilicon film layer. The annealing step can be conducted between the step S1 and the step S2, or after the step S2. In a preferred embodiment, the annealing step can be conducted between the step S1 and the step S2.

The annealing step conducted between the step S1 and the step S2 comprises that, after the deposition step, the temperature is increased to a fourth temperature to initiate in-situ rapid thermal annealing (RTA) to the first substrate 10. The atmosphere is transferred to hydrogen atmosphere. The gas flow rate of hydrogen can be 40 slm-80 slm, preferably 60 slm. The fourth temperature can be 1000° C.-1200° C., preferably, 1100° C.-1150° C.

The annealing step conducted after the step S2 comprises that, after the cooling step of the etching process, the temperature is increased to a fourth temperature to initiate in-situ RTA to the first substrate 10. The atmosphere is transferred to hydrogen atmosphere. The gas flow rate of hydrogen can be 40 slm-80 slm, preferably 60 slm. The fourth temperature can be 1000° C.-1200° C., preferably, 1100° C.-1150° C.

Subsequently, a second substrate 50 is provided. In one embodiment, an insulating buried oxide layer 40 is formed by a routine method, namely, an insulating buried oxide layer 40 is formed on the pinning layer 30. In another embodiment, an insulating buried oxide layer 40 is formed on the second substrate 50. In another embodiment, an insulating buried oxide layer 40 with a partial thickness is formed on the pinning layer 30, and the insulating buried oxide layer 40 with the remaining thickness is formed on the second substrate 50. The first substrate 10 is bonded with the second substrate 50 by a routine method to obtain the structure of HR-SOI embedded with a charge capture layer. The processes of forming the insulating buried oxide layer 40 and bonding the first substrate 10 with the second substrate 50 will not be limited herein, and can be the conventional processes known by a person having ordinary skills in the art.

Continue to referring FIG. 2 to FIG. 4, this embodiment also describes a structure of HR-SOI embedded with a charge capture layer comprising a first substrate 10, a surface treatment layer 20, a pinning layer 30, an insulating buried oxide layer 40 and a second substrate 50, stacked in sequence. The first substrate 10 can be a monocrystalline silicon semiconductor wafer with high resistivity. In one embodiment, the resistivity of the first substrate 10 can be 1 kΩ-10 kΩ. The first substrate 10 has a first surface 10a, and the surface treatment layer 20, the pinning layer 30, the insulating buried oxide layer 40 and the second substrate 50 are located on the side of the first surface 10a. The pinning layer 30 has a surface subjected to homogenization of dry etching. The second substrate 50 can be a monocrystalline silicon semiconductor wafer.

According to the above, the present application provides a structure of HR-SOI embedded with a charge capture layer and manufacture thereof. The process for manufacturing a structure of HR-SOI embedded with a charge capture layer comprises: providing a first substrate having a first surface, forming a pinning layer on the first surface by deposition, and homogenizing the pinning layer surface by dry etching to adjust a thickness uniformity of the pinning layer. Accordingly, the thickness uniformity of the obtained polysilicon film is able to reach a good state.

Unless the context clearly indicates otherwise, use of the words such as “first”, “second”, and “third” merely distinguish one component, element, step and the like from another component, element, step and the like, but does not indicate any sequence of the components, elements, steps and the like.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. A process for manufacturing a structure of high-resistivity silicon-on-insulator (HR-SOI) embedded with a charge capture layer comprising:
providing a first substrate having a first surface,
forming a pinning layer on the first surface by deposition, and
homogenizing the pinning layer surface by dry etching.

2. The process of claim 1, wherein the homogenizing step comprising: treating a surface of the pinning layer by hydrogen chloride (HCl) in situ etching to adjust a thickness uniformity of the pinning layer.

3. The process of claim 2, wherein the etching of the surface of the pinning layer is conducted under an atmosphere of a gaseous mixture of HCl and hydrogen (H₂) with a ratio of HCl: H₂ being 1:100-1:5, and an etching temperature of more than 1000° C.

4. The process of claim 1, further comprising an annealing step after the homogenizing step.

5. The process of claim 1, further comprising an annealing step after the formation of pinning layer and before the homogenizing step.

6. The process of claim 1, further comprising: prior to the formation of pinning layer, forming a surface treatment layer on the first surface of the first substrate, wherein the surface treatment layer is an oxide layer, a nitride layer or an oxynitride layer.

7. The process of claim 6, wherein, while the surface treatment layer is an oxide layer, the first surface is cleaned and washed to form the oxide layer.

8. The process of claim 6, wherein, while the surface treatment layer is a nitride layer or an oxynitride layer, the first surface is cleaned and washed to form an oxide layer, and the oxide layer is nitrided to form the nitride layer or the oxynitride layer.

9. The process of claim 6, wherein the formation of pinning layer comprises: forming a pinning layer on the first surface by chemical vapor deposition, wherein the pinning layer is a polysilicon film layer.

10. A high-resistivity silicon-on-insulator (HR-SOI) embedded with a charge capture layer characterized by,
manufactured by a process of claim 1, and
having a structure comprising a first substrate, a surface treatment layer and a pinning layer stacked in sequence,
wherein the first substrate has a first surface, and the surface treatment layer and the pinning layer are formed on the side of the first surface, and the pinning layer is subjected to homogenizing treatment by dry etching.

11. The HR-SOI embedded with a charge capture layer of claim 10, wherein the structure further comprises an insulating buried oxide layer and a second substrate stacked in sequence on the pinning layer.
